(19) United States
(12) Patent Application Publication
(10) Pub. No.: US 2025/0114952 A1
(43) Pub. Date: Apr. 10, 2025

(54) PICK AND PLACE HEAD WITH AUTOMATIC PITCH ADJUSTMENT

(71) Applicant: KLA Corporation, Milpitas, CA (US)

(72) Inventors: Jimmy Vermeulen, Sint-Agathat-Berchem (BE); KC Leung, Kwai Chung (HK); Ye Tan, Wespelaar (BE); Foon Ming Chan, Hong Kong (HK); KW Cheung, Tsing Yi, NT (HK); Bart De Mot, HongKong city (CN); Gabriel Mauricio Probst, Leuven city (BE)

(21) Appl. No.: 18/900,331

(22) Filed: Sep. 27, 2024

Related U.S. Application Data
(60) Provisional application No. 63/542,302, filed on Oct. 4, 2023.

(51) Int. Cl. B25J 15/06; H01L 21/67

(52) U.S. Cl. CPC B25J 15/0616; H01L 21/67144

(57) ABSTRACT

A transfer head may include a plurality of brackets and a plurality of front pickup shafts and rear pickup shafts slidably coupled to the plurality of brackets along a first axis, wherein at least one of the plurality of front pickup shafts and the rear pickup shafts are couplable to a pick-up gear. The transfer head may include a first axis pitch-change sub-system configured to slide the plurality of front pickup shafts relative to the plurality of rear pickup shafts. The transfer head may include a second axis pitch-change sub-system comprising: a cam comprising a plurality of cam slots configured to engage the plurality of brackets, wherein a movement of the cam causes a change in pitch between the plurality of brackets and a corresponding change in pitch between the plurality of the front pickup shafts and the rear pickup shafts along the second axis.

### CROSS-REFERENCE TO RELATED APPLICATION

The present application claims the benefit under 35 U.S.C. § 119(e) of U.S. Provisional Application Ser. No. 63/542,302, filed Oct. 4, 2023, naming Jimmy Vermeulen, K C Leung, Ye Tan, F M Chan, K W Cheung, Bart De Mot, and Gabriel Mauricio Probst as inventors, which is incorporated herein by reference in the entirety.

### TECHNICAL FIELD

The present invention relates to a pick-and-place head for picking workpieces, such as integrated circuit (IC) components, from one location and moving them to a different location. More specifically the present invention relates to automatic pitch conversion for pick up nozzle shafts of pick-and-place heads.

### BACKGROUND

Electronic components are often transported in carriers such as Joint Electron Device Engineering Council (JEDEC) trays during the manufacturing process. The components are placed in the cells of the trays, and placing components in cells is usually done by pick-and-place robots. A pick-and-place robot typically has several grippers (or pickers) that can pick up and remove an electronic component from a cell of a tray and also place an electronic component into a cell of a tray. The gripper may be mechanically clamping the electronic component or more commonly using vacuum nozzles.

In order to increase throughput, pick-and-place robots are often equipped with vacuum nozzles such that several components can be picked up or placed in parallel. Since components are of different sizes the number of components per tray row and column also differs and by that also the pitch between components. Therefore, the pitch between nozzles has to be adjustable and the number of nozzles has to be adaptable. The nozzles are commonly arranged in a row. In some cases, particularly for smaller components, two or more rows may be used in order to allow for further throughput increase.

In some pick-and-place products, the pitch between the rows and/or columns of nozzles is adjustable. However, changing the X and Y pitch of these nozzles is typically a manual process that requires specialized hardware accessories. Manual adjustment is a time-consuming process, and nozzle changeover hardware requires frequent cleaning and maintenance.

For pick and place products having automated pitch adjustment, the designs are often limited to having a low number of nozzle rows (e.g., less than three) and having a low number of nozzle shafts (e.g., less than nine). The low number of rows of nozzles, and the low overall number of nozzles, limit the number and type of electronic componentry that can be moved per unit of time, reducing productivity.

Therefore, it is desirable to provide methods that overcome the shortfalls of the previous approaches discussed above.

### SUMMARY

A transfer head of an electronic component handling system is disclosed, in accordance with one or more embodiments of the disclosure. In one illustrative embodiment, the transfer head includes a plurality of brackets; a plurality of front pickup shafts and a plurality of rear pickup shafts slidably coupled to the plurality of brackets along a first axis, wherein at least one of the plurality of front pickup shafts and the plurality of rear pickup shafts are couplable to a pick-up gear. In another illustrative embodiment, the transfer head includes a first axis pitch-change sub-system including: a set of front anchor blocks and a set of rear anchor blocks slidably coupled along the first axis to a first frame support and a second frame support; a set of front slide rods coupled to the set of front anchor blocks, wherein the plurality of front pickup shafts is slidably coupled to the set of front slide rods along a second axis; and a set of rear slide rods coupled to the set of rear anchor blocks, wherein the plurality of rear pickup shafts are slidably coupled to the set of rear slide rods along the second axis, wherein a sliding between the set of front anchor blocks and the set of rear anchor blocks causes a change in pitch between the plurality of front pickup shafts and the plurality of rear pickup shafts along the first axis. In another illustrative embodiment, the transfer head includes and a second axis pitch-change sub-system including: a cam including a plurality of cam slots configured to engage the plurality of brackets, wherein a movement of the cam causes a change in pitch between the plurality of brackets and a corresponding change in pitch between the plurality of front pickup shafts and the plurality of rear pickup shafts along the second axis, wherein one or more brackets of the plurality of brackets further comprises a center shaft coupled to a pick-up gear, wherein a translation of the set of front anchor blocks and the set of rear anchor blocks causes a change in pitch along the first axis between the center shaft and a one or more front pickup shafts of the plurality of front pickup shafts, and between the center shaft and one or more rear pickup shafts of the plurality of rear pickup shafts.

An electronic component handling system is disclosed, in accordance with one or more embodiments of the disclosure. In one illustrative embodiment, the electronic component handling system includes a transfer head including: a plurality of brackets; a plurality of front pickup shafts and a plurality of rear pickup shafts slidably coupled to the plurality of brackets along a first axis, wherein at least one of the plurality of front pickup shafts and the plurality of rear pickup shafts are couplable to a pick-up gear. In another illustrative embodiment, the electronic component handling system includes a first axis pitch-change sub-system including: a set of front anchor blocks and a set of rear anchor blocks slidably coupled along the first axis to a first frame support and a second frame support; a set of front slide rods coupled to the set of front anchor blocks, wherein the plurality of front pickup shafts is slidably coupled to the set of front slide rods along a second axis; and a set of rear slide rods coupled to the set of rear anchor blocks, wherein the plurality of rear pickup shafts are slidably coupled to the set of rear slide rods along the second axis, wherein a sliding between the set of front anchor blocks and the set of rear anchor blocks causes a change in pitch between the plurality of front pickup shafts and the plurality of rear pickup shafts along the first axis. In another illustrative embodiment, the electronic component handling system includes a second axis pitch-change sub-system including: a cam including a plurality of cam slots configured to engage the plurality of brackets, wherein a movement of the cam causes a change in pitch between the plurality of brackets and a corresponding change in pitch between the plurality of front pickup shafts and the plurality of rear pickup shafts along the second axis, wherein one or more brackets of the plurality of brackets further comprises a center shaft coupled to a pick-up gear, wherein a translation of the set of front anchor blocks and the set of rear anchor blocks causes a change in pitch along the first axis between the center shaft and a one or more front pickup shafts of the plurality of front pickup shafts, and between the center shaft and one or more rear pickup shafts of the plurality of rear pickup shafts; and a transfer head parking station.

A method for handling electronic components from a first location to a second location is disclosed, in accordance with one or more embodiments of the disclosure. In one illustrative embodiment, the method includes acquiring a first plurality of electronic components via a plurality of vacuum nozzles of a transfer head, wherein the plurality of vacuum nozzles are mechanically coupled to a plurality of front pickup shafts and a plurality of rear pickup shafts, wherein the plurality of front pickup shafts and the plurality of rear pickup shafts are slidably coupled to a plurality of brackets. In another illustrative embodiment, the method includes releasing the first plurality of electronic components at a process site. In another illustrative embodiment, the method includes adjusting a first axis pitch of the plurality of vacuum nozzles by translating along the plurality of brackets the plurality of front pickup shafts relative to the plurality of rear pickup shafts. In another illustrative embodiment, the method includes adjusting a second axis pitch via articulating a cam relative to the plurality of brackets, wherein the cam includes a plurality of cam slots mechanically coupled to the plurality of brackets that guide a translation of the plurality of brackets along a second axis, wherein adjusting the second axis pitch and the first axis pitch of the plurality of vacuum nozzles changes the plurality of vacuum nozzles from a first configuration to a second configuration. In another illustrative embodiment, the method includes acquiring a second plurality of electronic components via the plurality of vacuum nozzles of the transfer head. In another illustrative embodiment, the method includes releasing the second plurality of electronic components at the process site.

Another method for transferring electronic components from a first location to a second location is disclosed, in accordance with one or more embodiments of the disclosure. In one illustrative embodiment, the method includes acquiring a plurality of electronic components at the first location via a plurality of vacuum nozzles of a transfer head, wherein the plurality of vacuum nozzles are mechanically coupled to a plurality of front pickup shafts and a plurality of rear pickup shafts, wherein the plurality of front pickup shafts and a plurality of rear pickup shafts are slidably coupled to a plurality of brackets. In another illustrative embodiment, the method includes adjusting a first axis pitch of the plurality of vacuum nozzles by translating along the plurality of brackets the plurality of front pickup shafts relative to the plurality of rear pickup shafts. In another illustrative embodiment, the method includes adjusting a second axis pitch via articulating a cam relative to the plurality of brackets, wherein the cam includes a plurality of cam slots mechanically coupled to the plurality of brackets that guide a translation of the plurality of brackets along a second axis, wherein adjusting the second axis pitch and the first axis pitch of the plurality of vacuum nozzles changes the plurality of vacuum nozzles from a first configuration to a second configuration. In another illustrative embodiment, the method includes moving the transfer head to the second location.

### BRIEF DESCRIPTION OF THE DRAWINGS

The numerous advantages of the disclosure may be better understood by those skilled in the art by reference to the accompanying figures.

FIG. 1A illustrates a perspective view of a carriage of an electronic component handling system in accordance with one or more embodiments of the present disclosure.

FIG. 1B illustrates a perspective view of the transfer head, in accordance with one or more embodiments of the present disclosure.

FIG. 1C illustrates a front view of the transfer head, in accordance with one or more embodiments of the present disclosure.

FIG. 2. Illustrates a perspective view of a bracket assembly that includes bracket slidably coupled to a front pickup shaft and a rear pickup shaft, in accordance with one or more embodiments of the disclosure.

FIG. 3 illustrates a perspective view of a portion of the X-axis pitch-change sub-system, in accordance with one or more embodiments of the disclosure.

FIG. 4 illustrates a perspective view of a set of front slide rods and a set of rear slide rods coupled to a set of front anchor blocks and a set of rear anchor blocks, in accordance with one or more embodiments of the disclosure.

FIGS. 5A to 5B illustrate perspective views of the Y-axis pitch-change sub-system, in accordance with one or more embodiments of the disclosure.

FIGS. 5C to 5D illustrate outside and inside perspective views of the cam coupled to the rear panel, respectively, in accordance with one or more embodiments of the disclosure.

FIG. 5E illustrates a top perspective view of the transfer head, in accordance with one or more embodiments of the disclosure.

FIG. 6A illustrates a perspective view of a pick-up gear (PUG) interface, in accordance with one or more embodiments of the disclosure.

FIGS. 6B to 6D illustrate side views of various PUG inserts in accordance with one or more embodiments of the disclosure.

FIG. 7A illustrates a simplified schematic diagram of an electronic component handling system configured to pick up an object, in accordance with one or more embodiments of the disclosure.

FIG. 7B illustrates a simplified schematic diagram of an electronic component handling system configured to pick up an object and move the object from a tray to an image sensor, in accordance with one or more embodiments of the disclosure.

FIG. 7C illustrates a block diagram of a plurality of objects organized in a first configuration and a second configuration, in accordance with one or more embodiments of the disclosure.

FIG. 8 illustrates a process flow diagram depicting a method for transferring electronic components from a first location to a second location, in accordance with one or more embodiments of the disclosure.

FIG. 9 illustrates a process flow diagram depicting a method for transferring electronic components from a first location to a second location, in accordance with one or more embodiments of the disclosure.

### DETAILED DESCRIPTION

Reference will now be made in detail to the subject matter disclosed, which is illustrated in the accompanying drawings.

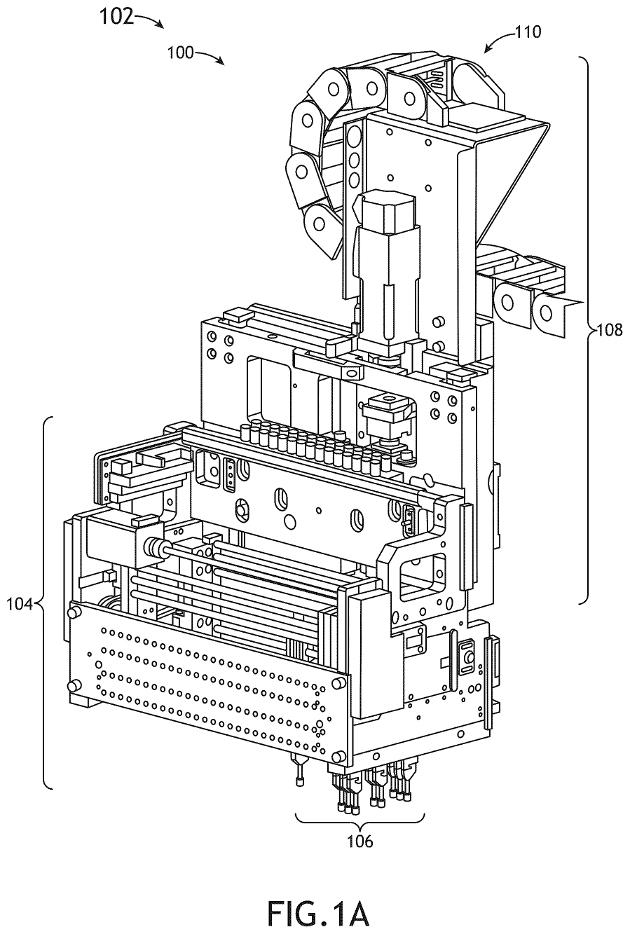

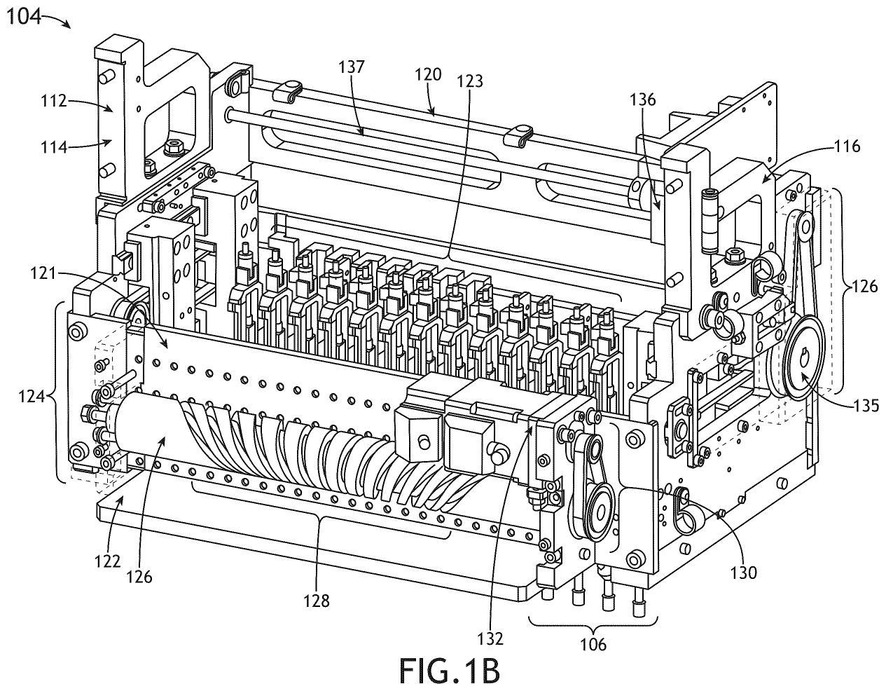

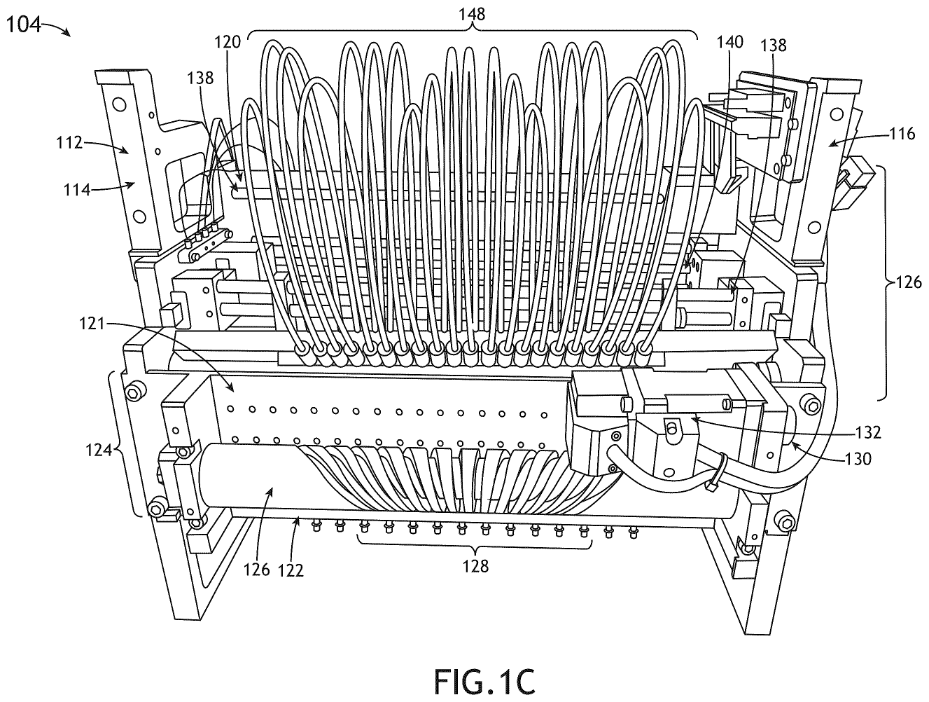

Referring generally to FIGS. 1A-9, a transfer head of an electronic component handling system is disclosed, in accordance with one or more embodiments of the present disclosure.

Embodiments of the present disclosure are directed to a transfer head of an electronic component handling system. The transfer head may be used in pick and place functions, such as for picking an electronic component from a first tray, and placing the electronic components into a second tray, or onto an electronic assembly. The pick-up function of the transfer head is performed via a set of vacuum nozzles that couple to the electronic components via suction. The pitch between the vacuum nozzles can be adjusted automatically via two pitch subsystems: an X-axis pitch change subsystem that changes the distance between front and rear rows of the nozzles, and a Y-axis pitch change subsystem that changes the distance between columns of nozzles via a cam. The electronic component handling system further includes a parking station that can receive the transfer head and adjust or activate/deactivate individual nozzles.

Embodiments of the present disclosure are particularly advantageous as the X and Y pitches of the nozzles can be adjusted automatically without the need for manual modifications. The use of the parking station to adjust and activate/deactivate individual nozzles automatically further decreases the loss of time for manual adjustment. Further, the design of the transfer head allows for a greater number of rows and columns of nozzles than previous pick and place heads, allowing the transfer head to pick and place larger items and/or multiple items at once. The transfer head and system described herein may enable a complete changeover of the nozzle configuration by recipe.

FIG. 1A illustrates a perspective view of a carriage 100 of an electronic component handling system 102 in accordance with one or more embodiments of the present disclosure. The carriage 100 includes a transfer head 104 that includes a set of tools (e.g., nozzles 106) that when activated can pick and place electronic components. For example, the set of tools may be configured as vacuum nozzles 106 that can latch onto electronic components via suction. The set of tools may also be configured with other latching mechanisms including, but not limited to, hooks and grippers. The carriage 100 includes an adapter assembly 108 that couples the transfer head 104 to other componentry of the electronic component handling system 102, such as a system frame (not shown). The carriage 100 may include a cable carrier 110 that delivers power to the transfer head 104.

FIG. 1B illustrates a perspective view of the transfer head 104, in accordance with one or more embodiments of the present disclosure. In embodiments, the transfer head 104 includes a head frame 112. The head frame 112 includes a first frame support 114 and a second frame support 116 on an opposite side. The head frame may further include a rear frame support 120 and a rear panel 121 couplable to the first frame support 114 and the second frame support 116. The head frame 112 may further include a bottom plate 122. Disposed within the headframe is a set of brackets 123 that support the set of nozzles 106 and nozzle shafts. The transfer head 104 may include other frame segments and panels and may include a protective cover.

In embodiments, the transfer head 104 includes a Y-axis pitch-change sub-system 124 (e.g., a second axis pitch-change sub-system) coupled to the head frame 112 (e.g., via the rear panel 121) and configured to adjust a pitch between two or more columns of nozzles 106 along a second axis (e.g., a Y-axis). The Y-axis pitch-change sub-system 124 may be configured to adjust any number of columns of nozzles. For example, the Y-axis pitch-change sub-system 124 may be configured to adjust the Y-axis pitch between 4 or more columns of nozzles 106, between 6 or more columns of nozzles, between 8 or more columns of nozzles, between 10 or more columns of nozzles, between 12 or more columns of nozzles, between 14 or more columns of nozzles, between 16 or more columns of nozzles, between 20 or more columns of nozzles, between 20 or more columns of nozzles. For instance, the Y-axis pitch-change sub-system 124 may be configured to adjust the Y-axis pitch between 14 columns of nozzles. Y-axis pitch-change sub-system 124 may be coupled to the head frame 112 via the rear panel 121.

In embodiments, the Y-axis pitch-change sub-system 124 includes a cam 126. The cam 126 may be configured to include a set of cam slots 128. The set of cam slots 128 may be configured such that a movement or articulation of the cam 126 causes the columns of nozzles to change pitch based on the profile of the cam slots 128 (e.g., the pitch between cam slots 128 changes over a length of the cam slots 128). For example, as the cam is moved and the distance between two cam slots 128 move away from each other (e.g., in the Y-axis direction), nozzles 106 associated with the two cam slots 128 will also move away from each other in the Y-axis direction, increasing the Y-axis pitch. The cam 126 is moved via cam gearing 130 powered by a cam motor 132.

In embodiments, the transfer head 104 includes an X-axis pitch-change sub-system 134 (e.g., a first axis pitch-change sub-system) coupled to the head frame. The X-axis pitch-change sub-system 134 may be configured to adjust any number of rows of nozzles 106. For example, the X-axis pitch-change sub-system 134 may be configured to adjust the X-axis pitch between 2 or more rows of nozzles 106, between 3 or more columns of nozzles, between 4 or more columns of nozzles, between 5 or more of nozzles, or between 6 or more of nozzles. For instance, a transfer head 104 may include a plurality of nozzles arranged in 14 columns and three rows. The X-axis pitch-change sub-system 134 may include one or more gear/pulley systems 135a-b. For example, the x-axis pitch-change sub-system 134 may include two gear/pulley systems (e.g. one on each side of the x-axis pitch-change sub-system 134) that use timing belts driven by a motor 136 (e.g., dual shaft stepper motor) that may enable synchronization between the front rows of nozzles 106 and rear rows of nozzles. In an alternative embodiment, the x-axis pitch-change sub-system 134 includes two independent motors 136 to control the X-axis motion of the front and rear rows of nozzles 106.

FIG. 1C illustrates a front view of the transfer head 104, in accordance with one or more embodiments of the present disclosure. In embodiments, the transfer head 104 includes a set of front slide rods 138 and a set of rear slide rods 140 that are slidably coupled to the set of nozzles 106, as shown herein. The transfer head 104 further includes a set of vacuum tubing 148 attached to corresponding vacuum nozzles 106. The

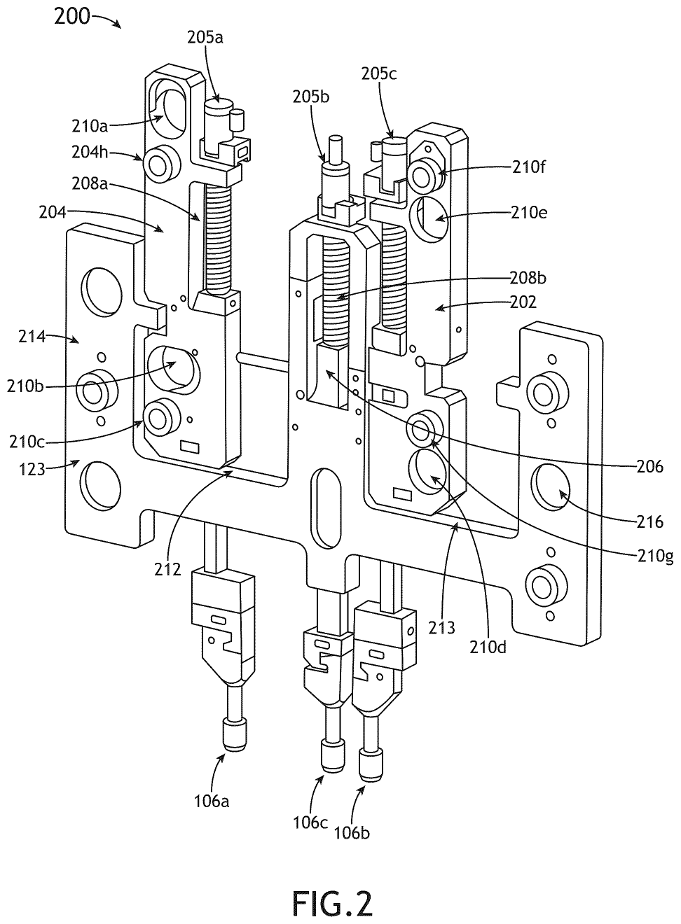

FIG. 2. Illustrates a perspective view of a bracket assembly 200 that includes a bracket 123 (e.g., illustrated as having an “E” shape) slidably coupled to a front pickup shaft 202 and a rear pickup shaft 204, in accordance with one or more embodiments of the disclosure. The front pickup shaft 202 and the rear pickup shaft 204 are coupled to nozzles 106a-b. the bracket 123 includes a center shaft 206 that is coupled to a nozzle 106c. The front pickup shaft 202, rear pickup shaft 204, and center shaft 206 further include shaft outlets 205a-c couplable to vacuum tubing 148. In this arrangement, when in operation, the electronic component handling system 102 creates a vacuum within the vacuum tubing 148 of the transfer head. The nozzles 106a-c, mechanically coupled to the vacuum tubing via the front pickup shaft 202, rear pickup shaft 204, and center shaft 206, create a suction that enables the nozzles 106 to pick up an electronic component. The bracket assembly 200 may include any number of front pickup shafts 202, rear pickup shafts 204, and center shafts 206. For example, the bracket assembly 200 may include four shafts, five shafts. six shafts, seven shafts, or eight or more shafts (e.g., made up of one or more front pickup shafts 202, rear pickup shafts 204, and center shafts 206). For example, the center shaft 206 may include a channel insert or pick up gear that provides the center shaft 206 with two, three, four, five, or six or more nozzles, each having the capacity to pick up an IC component. A plurality of bracket assemblies 200 may be implemented within the transfer head 104 to form a set of front, rear, and center nozzle row assemblies.

In embodiments, the front pickup shaft 202, rear pickup shaft 204, and center shaft 206 include shaft latches 208a-c that enable the nozzle 106a-c to be pushed upward into a latched position (e.g., an inactive position). Pushing nozzles 106 into a latched position enables the array of nozzles to be quickly customized for a specific pickup task. The shaft latches 208a-c may include any type of latch mechanism and include. The front pickup shaft 202, rear pickup shaft 204, and center shaft 206 also include a release mechanism, that when activated causes the front pickup shaft 202, rear pickup shaft 204, and center shaft 206 to return to an unlatched and active position. The release mechanism may include any type of mechanism or release component including, but not limited to, a spring. In an alternative embodiment, the front pickup shaft 202, rear pickup shaft 204, and center shaft 206 include actuators, such as pneumatic cylinders, to raise and/or lower the nozzles 106 along a Z-axis.

In embodiments, the front pickup shaft 202, rear pickup shaft 204, and/or center shaft 206 include one or more openings 210a-h (with some openings 210c, f, g, h shown fitted with linear bearings or linear motion guides). The openings 210 are configured to slidably couple with the set of front slide rods 138 or the set of rear slide rods 140. The bracket assembly 200 is configured such that the front pickup shaft 202, the rear pickup shaft 204, and the center shaft 206 slides in unison along the set of front slide rods 138 or set of rear slide rods 140, such when the cam 126 of the Y-axis pitch-change sub-system 124 is activated and/or turned.

In embodiments, the front pickup shaft 202 and the rear pickup shaft 204 are configured to slide along slots (e.g., a front pickup shaft slot 212 and a rear pickup shaft slot 213) of the bracket 123 relative to the center shaft 206. For example, the Y-axis pitch-change sub-system 134 may cause the set of front slide rods 138 and the set of rear slide rods 140 to translate away from each other, causing the front pickup shaft 202 and the rear pickup shaft 204 to slide away from the center shaft 206 increasing the Y-axis pitch between each nozzle 106a-c.

In embodiments, the bracket 123 includes one or more engagement legs 214a-b. The one or more engagement legs 214a-b provide added stability for the bracket assembly 200 and one or more of the engagement legs may be used for interacting with a respective cam slot 128 of the set of cam slots 128.

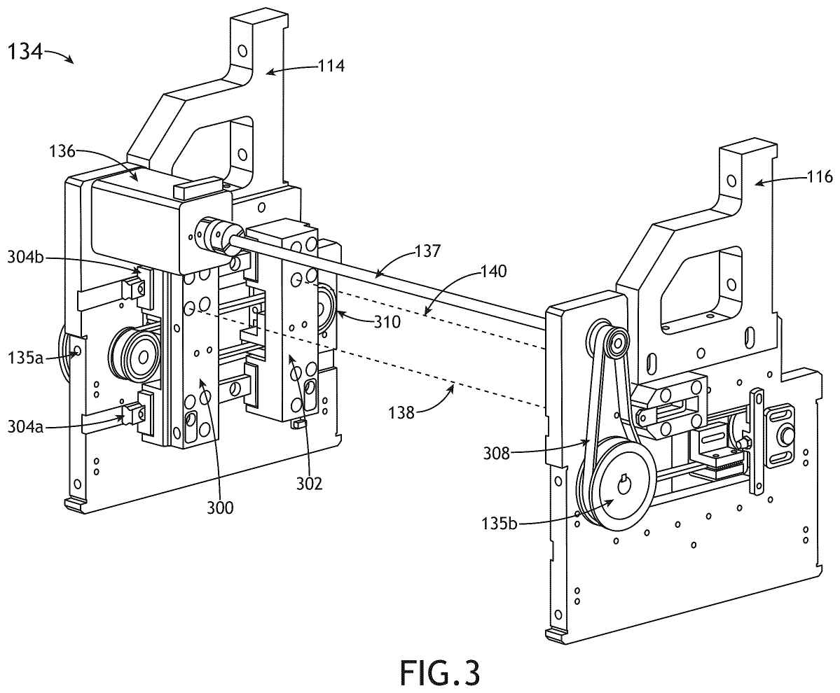

FIG. 3 illustrates a perspective view of a portion of the Y-axis pitch-change sub-system 134, in accordance with one or more embodiments of the disclosure. A placement of one shaft from each of the sets of front slide rods 138 and set of rear slide rods 140 are indicated by dotted lines. The X-axis pitch-change sub-system 134 includes or is coupled to the first frame support 114 and the second frame support 116. When activated, the motor 136 causes the gear shaft 137 to turn, which actuates the gear/pulley systems 135a-b, causing the set of front slide rods 138 and the set of rear slide rods 140 to translate relative to each other.

In embodiments, the X-axis pitch-change sub-system 134 includes a set of front anchor blocks 300 and a set of rear anchor blocks 302 couplable to the set of front slide rods 138 and rear slide rods 140, and slidably couplable to the first frame support 114 and second frame support 116 via one or more linear bearings 304a-b. The coupling of the second frame support 116 to the anchor blocks 300, 302 and linear bearing 304 is not visible as shown in FIG. 3. The sets of front anchor blocks 300 and rear anchor blocks are mechanically coupled to the gear/pulley systems 135a-b, allowing the movement of the gear/pulley systems 135a-b to be translated to the front slide rods 138 and rear slide rods 140.

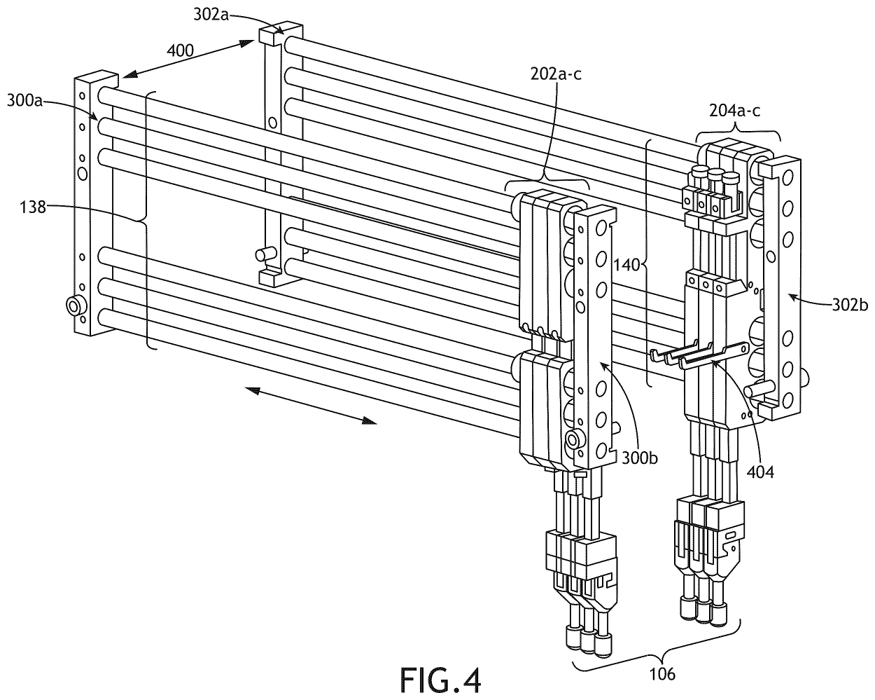

FIG. 4 illustrates a perspective view of a set of front slide rods 138 and a set of rear slide rods 140 coupled to a set of front anchor blocks 300a-b and a set of rear anchor blocks 302a-b, in accordance with one or more embodiments of the disclosure. FIG. 4 further includes three front pickup shafts 202a-c slidably coupled to the set of front slide rods 138 and three rear pickup shafts 204a-c slidably coupled to the set of rear slide rods 140. The bracket 123 has been omitted to show details of the front pickup shafts 202a-c and the rear pickup shafts 204a-c. Importantly, FIG. 4 illustrates how the nozzles 106 can translate along an X-axis 400 through a coordinated sliding of the anchor blocks 300a-b, 302a-b that adjusts the distances between the front pickup shafts 202a-c and the rear pickup shafts 204a-c (e.g., within the bracket assembly 200), and illustrates how the nozzles 106 can translate along a Y-axis 402 through a sliding of the front pickup shafts 202a-c and the rear pickup shafts 204a-c along the front pickup shafts 202a-c and the rear pickup shafts 204a-c.

In embodiments, when the bracket assembly 200 containing the front pickup shaft 202, the rear pickup shaft 204, and the center shaft 206 is incorporated into the x-axis pitch-change sub-system 134, and the set of front slide rods 138 and set of rear slide rods are translated, the front pickup shaft 202, the rear pickup shaft 204 are synchronized in that a change in pitch between front pickup shaft 202 and the center shaft 206 will correspond to a change in pitch between the rear pickup shaft 204 and the center shaft. For example, and as shown in FIG. 3, the gear/pully systems 135a-b include an upper belt section 308 coupled to the set of front anchor blocks 300 and a lower belt section 310 coupled to the set of rear anchor blocks 302. When the belts 308, 310 are driven by the motor 136, the set of front slide rods 138 and the set of rear slide rods 140 will move (e.g., in opposite directions). In this manner, the x-axis pitch-change sub-system 134 causes similar changes in pitch between the rows of nozzles 106.

In embodiments, front pickup shafts 202a-c and/or the rear pickup shafts 204a-c 404 include a bracket latch 404. The bracket latch 404 clamps the front pickup shafts 202a-c and/or the rear pickup shafts 204a-c to the center shaft 206. The bracket latch 404 may be activated/inactivated manually or automatically. The bracket latch 404 may assist the transfer head 104 in maintaining a specific nozzle configuration.

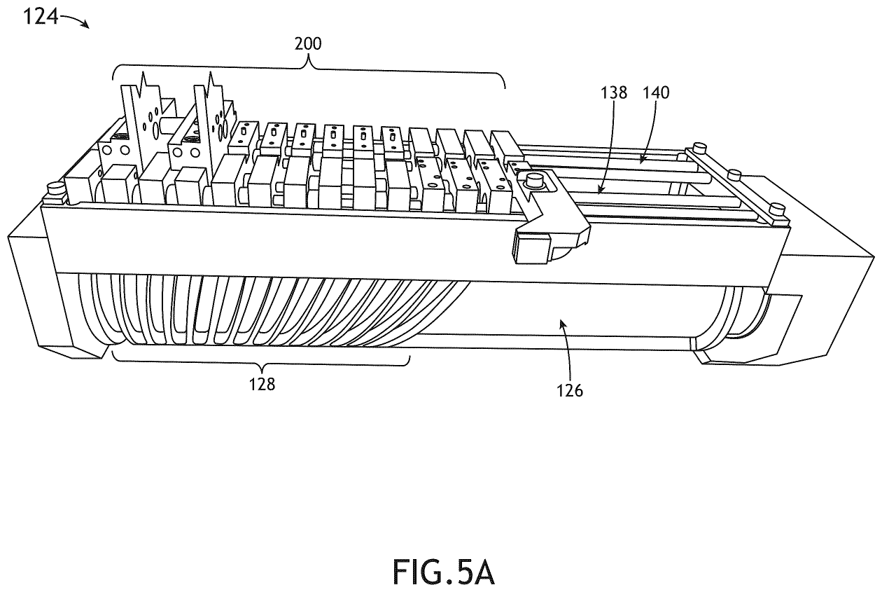

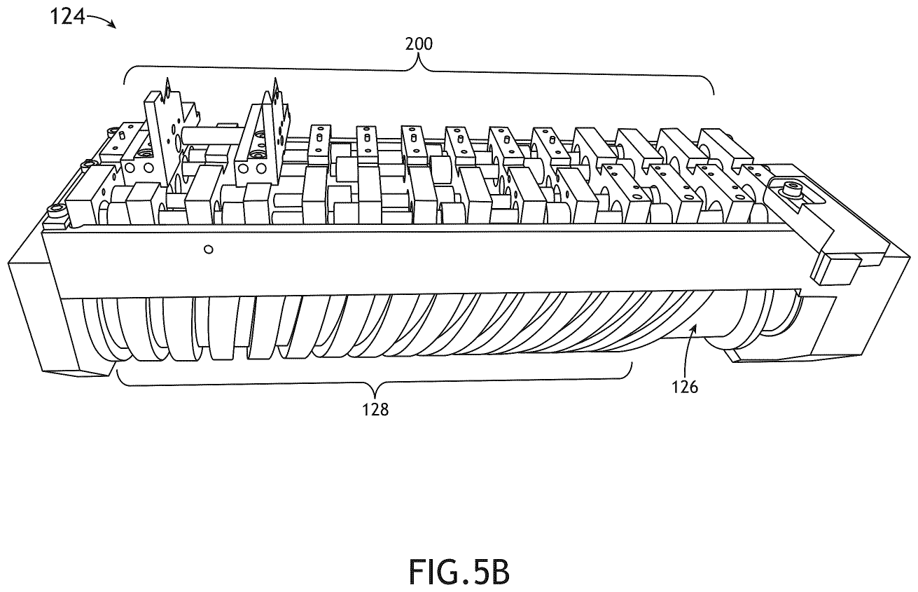

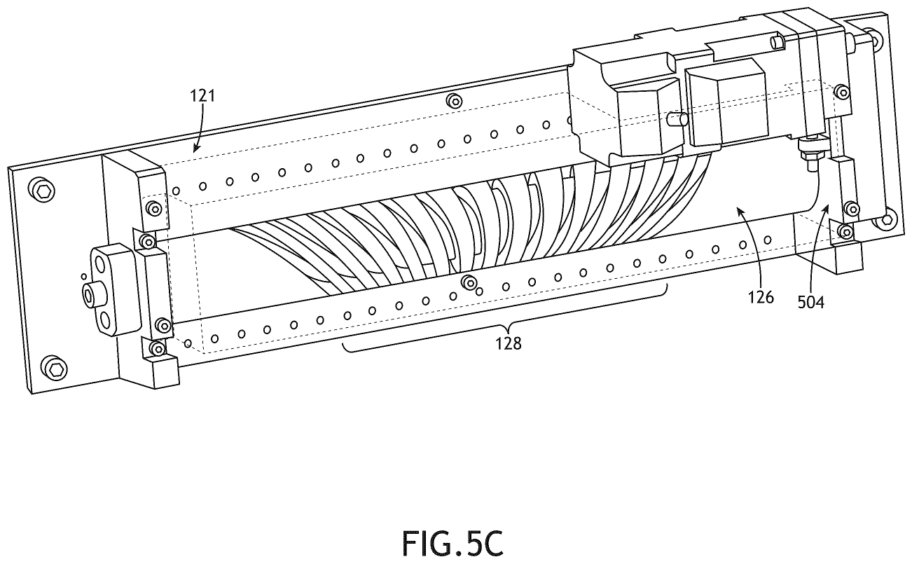

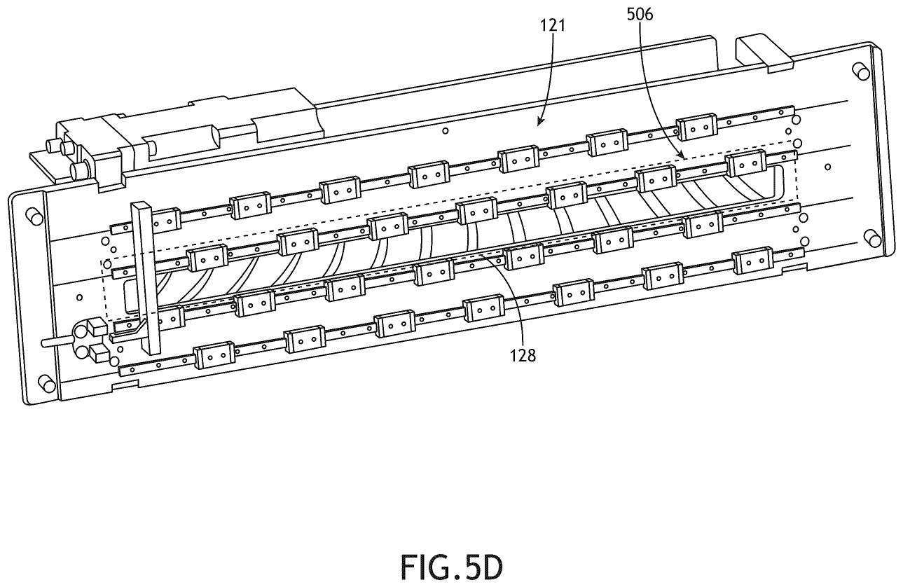

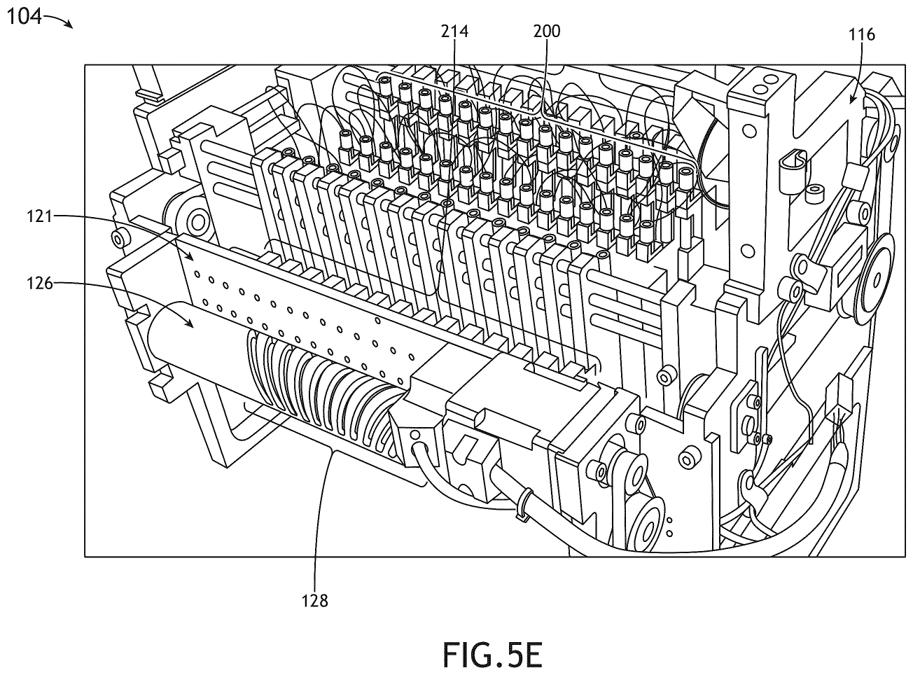

FIGS. 5A to 5B illustrate perspective views of the Y-axis pitch-change sub-system 124, in accordance with one or more embodiments of the disclosure. The Y-axis pitch-change sub-system 124 may include a cam 126 (e.g., a drum cam) with a set of cam slots 128. The Y-axis pitch-change sub-system 124 may further include a set of front slide rods 138 and a set of rear slide rods 140. The Y-axis pitch-change sub-system 124 may further include a set of bracket assemblies 200 coupled to the set of front slide rods 138 and the set of rear slide rods 140. In an alternative embodiment, the Y-axis pitch-change sub-system 124 includes a second drum cam (e.g., attached to the side opposite the first drum cam 126) that is couplable to a second engagement leg or follower cam, providing a greater force and/or stability toward the Y-axis movement of the bracket assemblies 200. While a drum cam 126 is shown, other cam designs can be used, including, but not limited to, a wedge cam.

The cam 126 may include any pattern or arrangement of cam slots 128. For example, the cam 126 may include a set of cam slots 128 arranged in a centered formation (e.g., as illustrated in FIGS. 1A-1B), where the cam slots 128 positioned towards a midline of the cam 126 are approximately normal to a circular cross section of the cam 126, whereas the cam slots positioned away from the midline of the cam 126 are slanted. In another example, the cam 126 may include a set of cam slots arranged in a skewed formation (e.g., as illustrated in FIGS. 5A-5B), where the cam slots are positioned toward one side of the cam 126. In this skewed formation, the cam slots 128 positioned near an end of the cam are approximately normal to the circular cross section of the cam 126, whereas the cam slots 128 positioned toward a midline of the cam 126 are slanted. Therefore, the description above is intended as an illustration of an embodiment of the cam 126, not as a limitation.

In embodiments, one or more cam slots 128 of the cam 126 interacts with, or is mechanically coupled to, one or more engagement legs 214a-b of a bracket 123. For example, when the cam 126 rotates, the cam slot 128 guides the engagement leg 214 and/or a cam follower coupled to the engagement leg, guiding the bracket assembly 200 along the Y-axis. For example, referring to FIG. 5A, the cam 126 has been rotated to a position where the cam slots 128 are engaged with their respective bracket assembly 200 (e.g., via the engagement leg 214) in a tight formation. Upon rotation of the cam 126, the engagement legs 214 remain in contact with the cam slots 128 so that when the cam slots turned to a “wide” formation, the bracket assemblies 200 are also positioned to a wide formation, as shown in FIG. 5B. In embodiments, the transfer head 104 may include other cam follower-adapting elements that engage the cam slots 128 and bias the sliding of the bracket assemblies 200 along the front slide rods 138 and rear slide rods 140 based on the engagement.

FIGS. 5C and 5D illustrate outside and inside perspective views of the cam 126 coupled to the rear panel 121, respectively, in accordance with one or more embodiments of the disclosure. The cam 126 is shown covered by a semitransparent cover 504. As shown in FIG. 5D, the cam slots 128 of the cam 126 are visible via an engagement window 506 that allows the cam slots to interact with the engagement legs 214 of the bracket assemblies 200. The engagement window 506 defines an interface between the cam slots 128 and the engagement legs 214 or cam followers.

FIG. 5E illustrates a top perspective view of the transfer head 104, in accordance with one or more embodiments of the disclosure. FIG. 5E more clearly illustrates the interaction of the cam slots 128 with the engagement legs 214 of the bracket assembly 200 via the engagement window 506 of the rear panel 121 (the window in FIG. 5E is hidden from view). In embodiments, a movement (e.g., rotation or articulation) of the cam 126 causes a change in pitch between the plurality of bracket assemblies 200, and a corresponding change in pitch between the associated front pickup shafts 202 and rear pickup shafts 204. Although the cam 126 is shown coupled to the rear panel 121, the transfer head 104 may be constructed such that the cam is not coupled to the rear panel while still engaging with other components of the y-axis pitch-change sub-system 124. Therefore, the description above is intended as an illustration of an embodiment of the transfer head 104, not as a limitation.

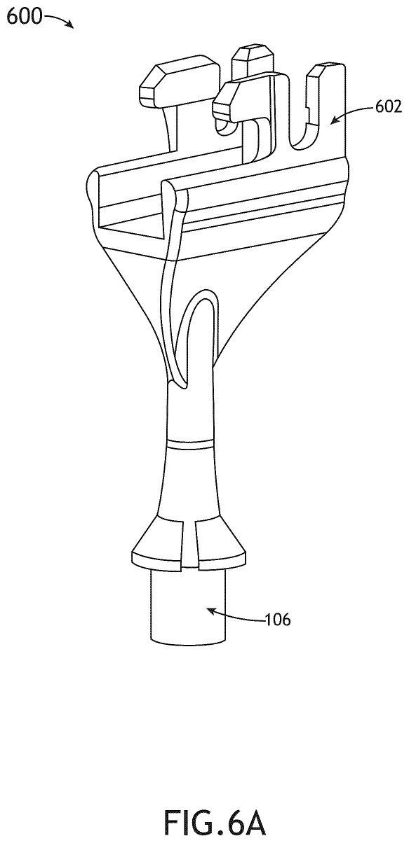

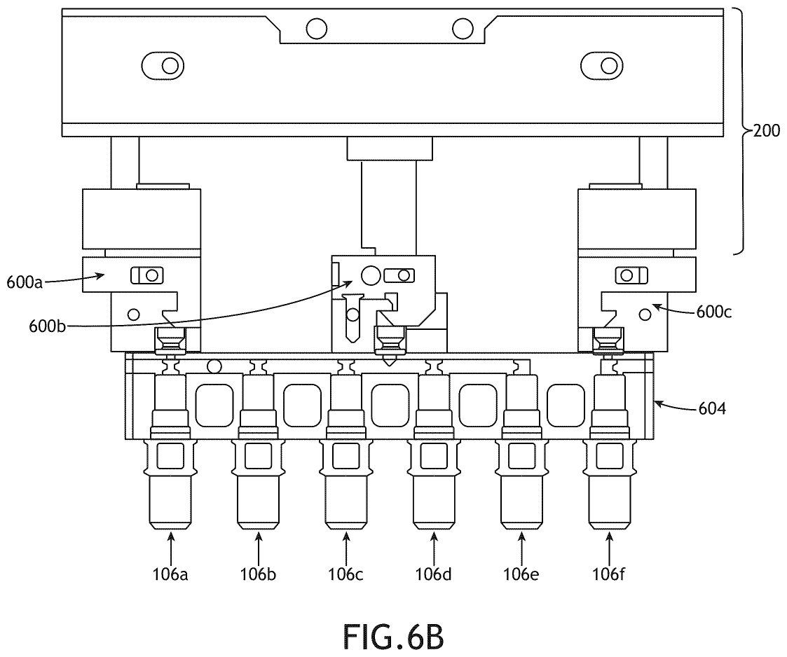

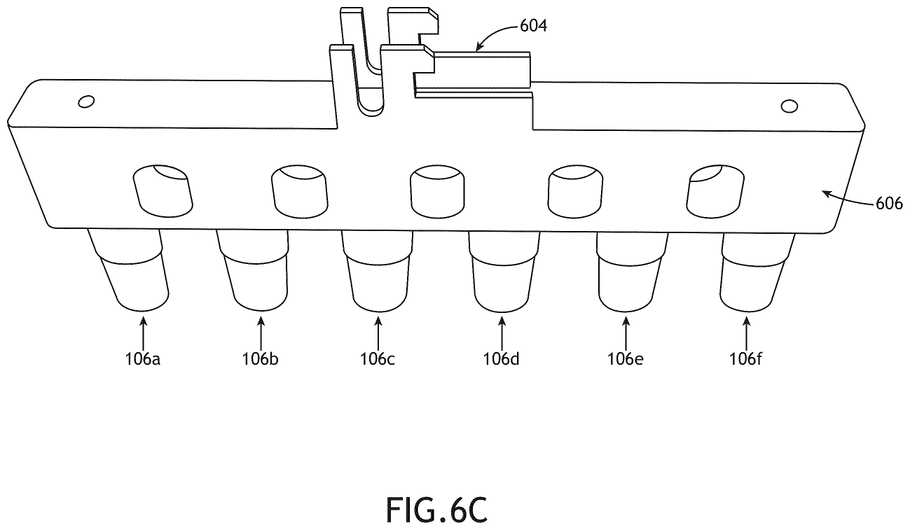

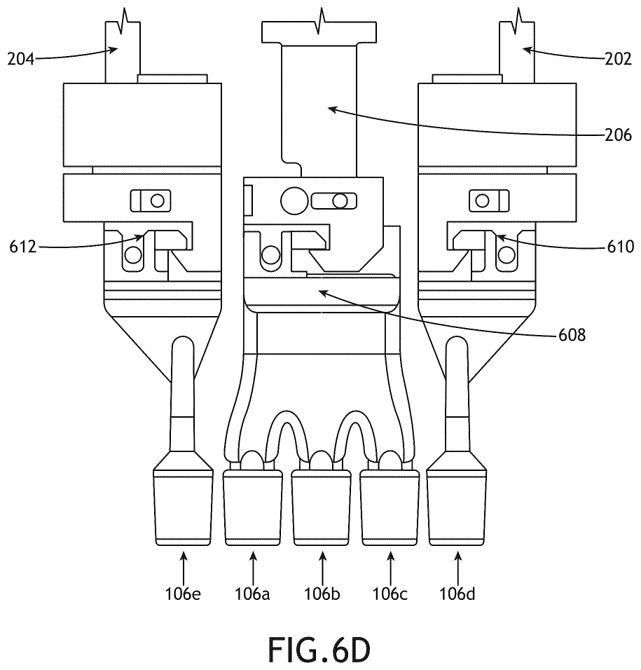

FIG. 6A illustrates a perspective view of a pick-up gear (PUG) 600, in accordance with one or more embodiments of the disclosure. The PUG 600 or PUG insert is an insert that can quickly connect to the front pickup shaft 202, the rear pickup shaft 204, and the center shaft 206. The PUG 600 may include a nozzle 106, may be couplable to a nozzle 106, or may include a primary nozzle 106 that is couplable to a secondary nozzle 106. The PUG 600 includes an interface 602 that can quickly attach to the front pickup shaft 202, the rear pickup shaft 204 and/or the center shaft 206.

FIGS. 6B-6D illustrate side views of the various PUG inserts 600 in accordance with one or more embodiments of the disclosure. The PUG insert 600 may include any number of nozzles 106, or secondary nozzles, per shaft (e.g., 2, 3, 4, 5, 6, 7, 8 or more nozzles 106 per shaft). To support multiple nozzles 106 per shaft, the PUG insert 600 may be designed to with split air channels, allowing air/vacuum to reach each nozzle 106. For example, FIG. 6B illustrates a set of three PUG inserts 600a-c coupled to a bracket assembly 200, with the three PUG inserts 600a-c further coupled to a nozzle set 604 containing six secondary nozzles 106a-f (e.g., multirow inserts). In another example, FIG. 6C illustrates a PUG insert 606 containing six secondary nozzles 106a-f that couple to the bracket assembly 200 via a single interface 602. In another example, FIG. 6D illustrates a single central PUG insert 608 coupled to a center shaft 206 and three nozzles 106a-c. The single central PUG insert 608 is flanked on one side by a PUG insert 610 coupled to a front pickup shaft 202 and a single nozzle 106d and flanked on the other side by a PUG insert 612 coupled to a 204 and a single nozzle 106e. The ability of the PUG inserts 600 to couple the front pickup shaft 202, the rear pickup shaft 204, and/or the center shaft 206 to multiple nozzles 106 increases the number of nozzle rows that can be operated by the transfer head 104. For example, a transfer head 104 operating with a bracket assembly 200 that has been fitted with the PUG insert system of FIG. 6B now includes six rows of nozzles for transferring IC components.

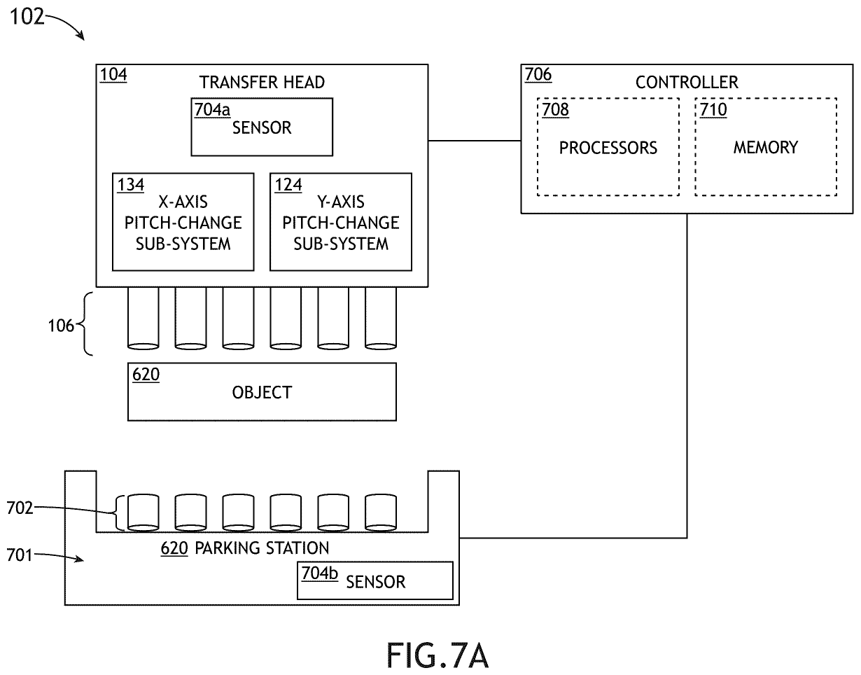

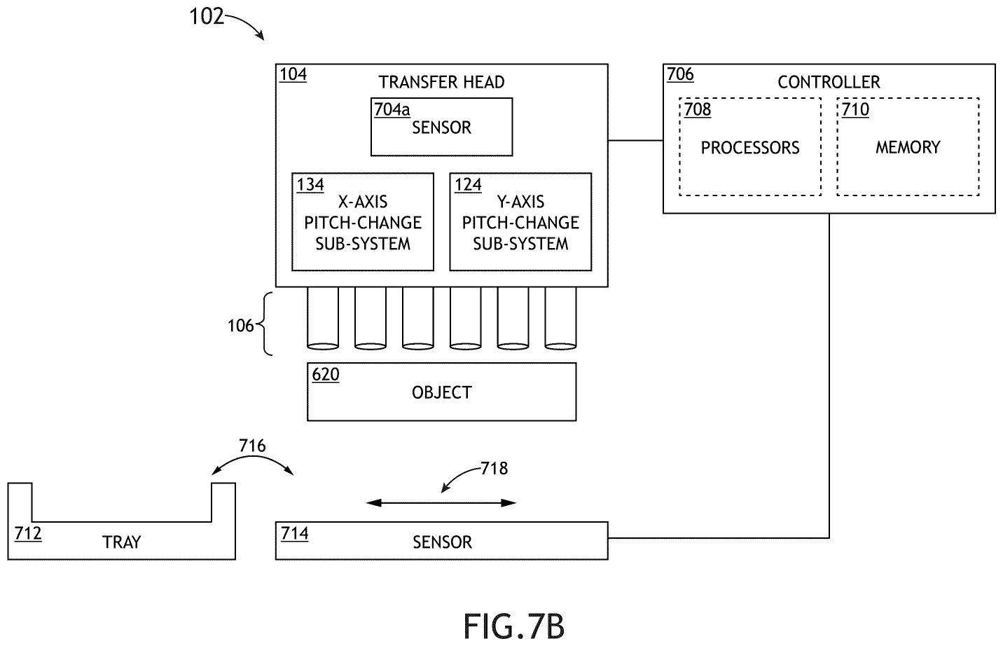

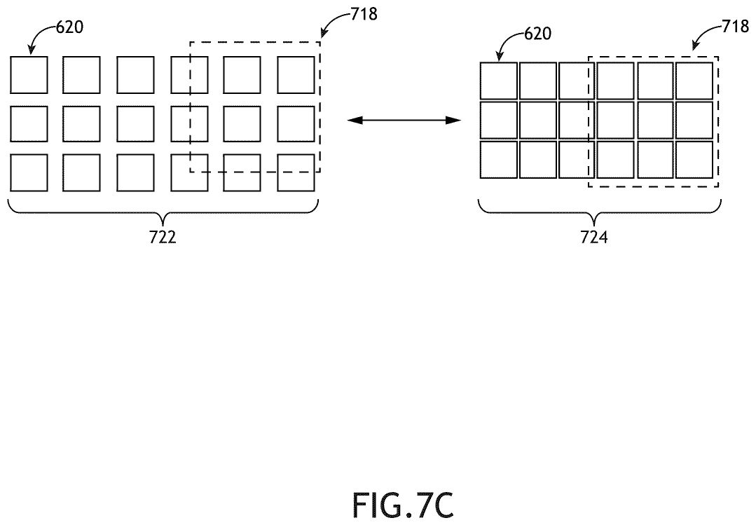

FIG. 7A illustrates a simplified schematic diagram of the electronic component handling system 102 configured to pick up an object 620 (e.g., an electronic component), in accordance with one or more embodiments of the disclosure.

In embodiments, the electronic component handling system 102 includes a transfer head parking station 700. The transfer head parking station 700 provides a docking space (e.g., a base 701) for the transfer head 104. The transfer head parking station 700 may also direct or otherwise cause the nozzles 106 to form specific configurations of active and inactive nozzles 106. For example, the transfer head parking station 700 may include a pusher assembly that includes a set or plurality of individual pushers 702 (e.g., mechanical, hydraulic, or pneumatic pushers) that correspond to respective nozzles 106. The transfer head parking station 700 may further include valves (e.g., pneumatic valves) and manifolds as required to activate the pushers 702. When the transfer head 104 is docked in the transfer head parking station 700, the set of pushers 702 within the pusher assembly pushes or bias the nozzles 106 upward, locking them in an inactive configuration or position. In this manner, the transfer head parking station 700 automates the settings of the nozzles 106 for different configurations. The transfer head parking station 700 and/or transfer head 104 may also be configured with a global release mechanism that releases all nozzles 106 from the inactive configuration or position to an active configuration or position.

In embodiments, the transfer head 104 and/or the transfer head parking station 700 include one or more sensors 704a-b. The one or more sensors 704a-b may be configured to detect or determine one or more of a position, an active state, or a configuration of the transfer head 104 and/or nozzles 106. For example, the one or more sensors 704a-b may check the configuration of the transfer head 104 to ensure that the pattern of active and inactive nozzles 106 is correct for the electronic object being picked. The sensors 704a-b may include any type of sensor including, but not limited to, optical sensors 704.

FIG. 7B illustrates a simplified schematic diagram of an electronic component handling system 102 configured to pick up objects 620 and move the objects 620 from a tray 712 (or any other location) to an image sensor 714, in accordance with one or more embodiments of the disclosure. In embodiments, the electronic component handling system 102 is coupled and/or associated with an image sensor 714 as part of an inspection process. For example, objects 620, such as a plurality of IC components, are picked up by the transfer head 104 from the tray 712 and moved (e.g., transferred 716) over to the image sensor 714 where images and/or other data are taken.

In embodiments, the electronic component handling system 102 may modify pitches between the objects 620 while held by the nozzles 106. For example, the electronic component handling system 102 may decrease a spacing (e.g., X-axis pitch and/or Y-axis pitch) between the objects 620 prior to imaging with the image sensor 714 to adjust or in some cases maximize a number of objects 620 that fit within a field of view of the imaging sensor 714.

FIG. 7C illustrates a block diagram of a plurality of objects 620 organized in a first configuration 722 and a second configuration, in accordance with one or more embodiments of the disclosure. For example, the first configuration 722 may represent an initial configuration of the plurality of objects 620 organized on a tray and waiting to be picked up by the transfer head 104 (e.g., each object picked up by a single nozzle) and imaged by the image sensor 714. However, in this non-limiting example, the field of view 718 of the image sensor 714 only allows four objects 620 of the plurality of object to be completely imaged while the plurality of objects 620 are arranged in the first configuration 722. Scanning of the objects 620 in the first configuration is relatively inefficient, as it would take six images by the image sensor 714 to image all of the objects 620. However, by picking up the plurality of objects 620 in the first configuration 722 and adjusting the X-axis pitch and Y-axis pitch (e.g., via the x-axis pitch-change sub-system 134 and y-axis pitch-change sub-system 124), the transfer head 104 organizes the plurality of objects 620 into a more compact second configuration, allowing nine objects 620 to be scanned at one time (e.g., as the nine objects can be positioned within the field of view 718 of the image sensor. Organizing the plurality of object 620 from the first configuration 722 to the second configuration 724 also reduces the number of images that need to be taken from the image sensor 714 from six images to two images. It is to be understood, however, that FIG. 7C and the associated description are merely illustrative and not limiting on the scope of the present disclosure. The electronic component handling system 102 may adjust the spacing between the objects 620 to any configuration suitable for imaging such that any number of objects 620 may fit within any field of view of any desired imaging sensor 714.

In embodiments, the electronic component handling system 102 is communicatively coupled to a controller 706. For example, various components of the electronic component handling system 102 such as the transfer head 104 and the transfer head parking station 700 may be communicatively coupled to the controller 706. For instance, one or more control elements (e.g., one or more pumps or valves configured to selectively create or adjust the vacuum to the transfer head 104) may be communicatively coupled to and controlled by controller 706. In another instance, the controller 706 may control the positioning of the transfer head 104. In another instance, the set of individual pushers 702 of the transfer head parking station 700 may be controlled by the controller 706. In another instance, one or more sensors 704a-b for sensing one or more conditions related to an object 620, the one or more nozzles 106, and/or the set of individual pushers 702 may be communicatively coupled to the controller and/or configured to transmit sensing data to the controller 706. The components of the transfer head 104 and/or set of individual pushers 702 may be communicatively coupled to each other and/or to the controller 706 via a wireline (e.g., copper wire, fiber optic cable, and the like) or wireless connection (e.g., RF coupling, IR coupling, data network communication (e.g., Wi-Fi, WiMax, Bluetooth and the like), or in any other manner known in the art.

In embodiments, the controller 706 may be configured to receive information from the one or more sensors 704a-b. The controller 706 may be configured to use the received information to adjust one or more conditions of the transfer head 104, the transfer head parking station 700, and/or other components of the electronic component handling system 102. The one or more conditions of the transfer head 104, the transfer head parking station 700, and/or other components of the electronic component handling system 102 may include, but are not limited to, a nozzle active state, fluid flow/vacuum strength, nozzle position and/or orientation, and pusher position and/or orientation.

The one or more processors 708 of controller 706 may include any one or more processing elements known in the art. In this sense, the one or more processors 708 may include any microprocessor-type device configured to execute software algorithms and/or instructions. In embodiments, the one or more processors 708 may consist of a desktop computer, mainframe computer system, workstation, image computer, parallel processor, or other computer system (e.g., networked computer) configured to execute a program configured to operate the system 102, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from a non-transitory memory medium 710. Moreover, different subsystems of the system 102 (e.g., the transfer head 104 or the transfer head parking station 700) may include a processor 708 or logic elements suitable for carrying out at least a portion of the steps described throughout the present disclosure.

The memory medium 710 may include any memory medium known in the art suitable for storing program instructions executable by the associated one or more processors 708. For example, the memory medium 710 may include, but is not limited to, a read-only memory, a random-access memory, a magnetic or optical memory device (e.g., disk), a magnetic tape, and a solid-state drive. In embodiments, the memory medium 710 is configured to store one or more results from the electronic component handling system 102 and/or the output of the various data processing steps described herein. It is further noted that memory medium 710 may be housed in a common controller housing with the one or more processors 708. In an alternative embodiment, the memory medium 710 may be located remotely with respect to the physical location of the processors and controller 706. For instance, the one or more processors 708 of controller 706 may access a remote memory (e.g., server), accessible through a network (e.g., internet or intranet).

It is further noted that, while FIGS. 7A-7B depicts the controller 706 as being embodied separately from the transfer head 104 and the transfer head parking station 700, such a configuration of system 102 is not a limitation on the scope of the present disclosure but is provided merely for illustrative purposes. For example, the controller 706 may be embodied in a controller of the transfer head 104 and/or the transfer head parking station 700.

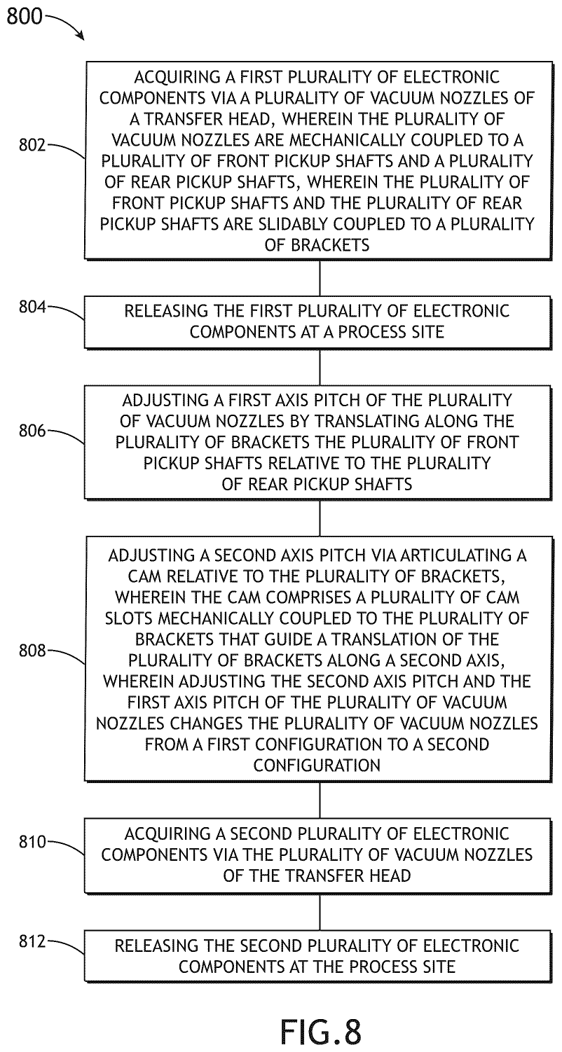

FIG. 8 illustrates a process flow diagram depicting a method 800 for transferring a plurality of electronic components from a first location (e.g., a first tray) to a second location (e.g., a second tray or process site), in accordance with one or more embodiments of the disclosure. The method 800 may be performed via the transfer head 104 as detailed herein. In embodiments, the method 800 includes a step 802 of acquiring a first plurality of electronic components via a plurality of vacuum nozzles of a transfer head, wherein the plurality of vacuum nozzles are mechanically coupled to a plurality of front pickup shafts and a plurality of rear pickup shafts, wherein the plurality of front pickup shafts and the plurality of rear pickup shafts are slidably coupled to a plurality of brackets. For example, the nozzles 106 of the transfer head 104 may be arranged in a first configuration where the X-pitches and Y-pitches between nozzles are relatively small (e.g., due to the objecting having small pickup surfaces or the plurality of objects being packed within a small space). The first configuration may also include several nozzles 106 that have been inactivated by having been biased upward to the inactive position, either manually or automatically via the transfer head parking station 700.

In embodiments, the method 800 includes a step 804 of releasing the first plurality of electronic components at a process site. For example, once the transfer head 104 has moved to the first electronic component and picked up the first electronic object via the vacuum nozzles 106, the transfer head 104 may then be moved to the process site, where the transfer head 104 releases the first electronic object by releasing the vacuum to the nozzles 106.

In embodiments, the method 800 includes a step 806 of adjusting a first axis pitch of the plurality of vacuum nozzles 106 by translating along the plurality of brackets 123 the plurality of front pickup shafts 202 relative to the plurality of rear pickup shafts 206. For example, the controller 706 may cause the motor 136 of the Y-axis pitch-change sub-system 134 to actuate the gear/pulley systems 135a-b causing the set of front slide rods 138 and the set of rear slide rods 140 to translate relative to each other, and correspondingly, the front pickup shafts 202 and rear pickup shafts 206 to translate relative to each other.

In embodiments, the method includes a step 808 of adjusting a second axis pitch via articulating a cam 126 relative to the plurality of brackets 123, wherein the cam 126 comprises a plurality of cam slots 128 mechanically coupled to the plurality of brackets 123 that guide a translation of the plurality of brackets 123 along a second axis, wherein adjusting the second axis pitch and the first axis pitch of the plurality of vacuum nozzles 106 changes the plurality of vacuum nozzles 106 from a first configuration to a second configuration. For example, the second plurality of electronic components may be configured as a set of components widely spaced on a tray, and the nozzles 106 of the transfer head 104 may be arranged to a second configuration where the X-pitches and Y-pitches between nozzles 106 are also relatively large. The second configuration may also require include nozzles 106 that were initially inactivated in the first configuration to be activated by activating the release mechanism either manually, or automatically via the transfer head 104 and/or the transfer head parking station 700. The steps 806 and 808 of adjusting the first and second axis pitches may be carried out either simultaneously or sequentially in any order. In this way, the depiction of step 806 prior to the step 808 in FIG. 8 is merely illustrative and not limiting on the scope of the present disclosure.

In embodiments, the method 800 includes a step 810 of acquiring a second plurality of electronic components via the plurality of vacuum nozzles of the transfer head. In embodiments, the method 800 includes a step 812 of releasing the second plurality of electronic components at the process site.

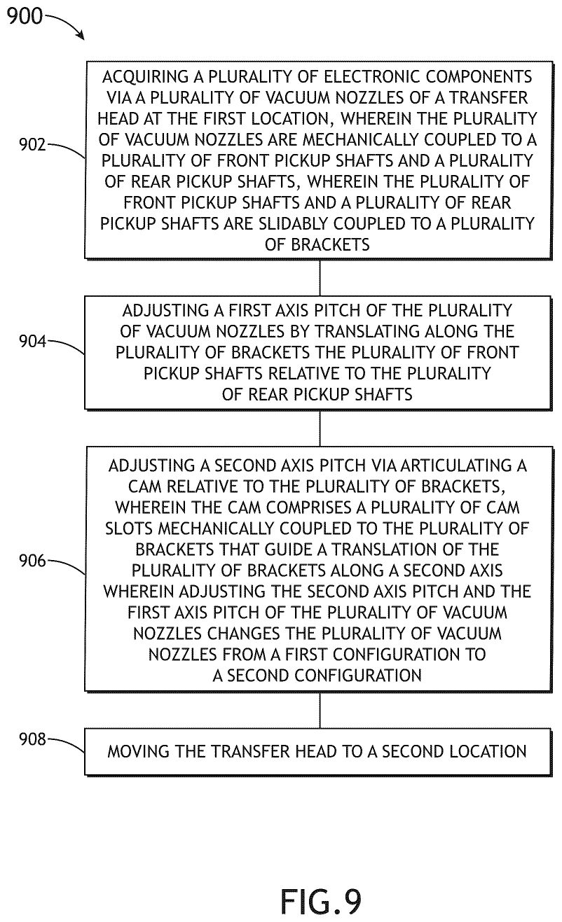

FIG. 9 illustrates a process flow diagram depicting a method 900 for acquiring a plurality of electronic components from a first location in a first configuration 722 and adjusting the plurality of electronic components to a second configuration 724, in accordance with one or more embodiments of the disclosure. The method 900 may be performed via the transfer head 104 as detailed herein.

In embodiments, the method 900 includes a step 902 of acquiring a first plurality of electronic components at the first location via a plurality of vacuum nozzles 106 of a transfer head 104, wherein the plurality of vacuum nozzles 106 are mechanically coupled to a plurality of front pickup shafts 202 and a plurality of rear pickup shafts 204, wherein the plurality of front pickup shafts 202 and the plurality of rear pickup shafts 204 are slidably coupled to a plurality of brackets 123. For example, the transfer head 104 may have a plurality of nozzles arranged in a first configuration (e.g., a wide configuration) that allows the transfer head to pick up a several objects widely spaced on a tray.

In embodiments, the method 900 includes a step 904 of adjusting a first axis pitch of the plurality of vacuum nozzles 106 by translating along the plurality of brackets 123 the plurality of front pickup shafts 202 relative to the plurality of rear pickup shafts 204. For example, the first axis pitches may be adjusted via the x-axis pitch-change sub-system 134.

In embodiments, the method 900 includes a step 906 of adjusting a second axis pitch via articulating a cam relative to the plurality of brackets, wherein the cam 126 comprises a plurality of cam slots 128 mechanically coupled to the plurality of brackets 123 that guide a translation of the plurality of brackets 123 along a second axis, wherein adjusting the second axis pitch and the first axis pitch of the plurality of vacuum nozzles 106 changes the plurality of vacuum nozzles 106 from a first configuration to a second configuration. In embodiments, the method includes a step 908 of moving the transfer head 104 to a second location (e.g., for the plurality of objects 620 to be processed or imaged). Once the processing is complete, the image head 104 may change from the second configuration 724 to the first configuration 722 return the plurality of objects 620 to the tray 712 or other location. For example, the image head may change from a second configuration to a third new configuration, and/or transfer the plurality of objects to a different location.

In embodiments, the X-axis pitch-change sub-system 134 and the Y-axis pitch-change sub-system 124 can be adjusted simultaneously. For example, as transfer head 104 is moving from the first location to the second location, both the X-axis pitch-change sub-system 134 and the y-axis pitch-change sub-system 124 may be activated, resulting in a simultaneous change in the first axis pitch and the second axis pitch. Further, Z-axis (e.g., third-axis) changes in the of nozzles 106 (e.g., adjusting a height of the nozzles 106 as performed by actuators in the transfer head 104) may also be performed simultaneously along with the X-axis pitch-change, the Y-axis pitch change, or the X-axis and the Y-axis pitch change.

While implementations of methods 800, 900 are discussed herein, it is further contemplated that various steps of the methods 800, 900 may be included, excluded, rearranged, and/or implemented in many ways without departing from the essence of the present disclosure. Accordingly, the foregoing embodiments and implementations of methods 800, 900 are included by way of example only and are not intended to limit the present disclosure in any way.

All of the methods described herein may include storing results of one or more steps of the method embodiments in a memory medium. The results may include any of the results described herein and may be stored in any manner known in the art. The memory medium may include any memory medium described herein, or any other suitable memory medium known in the art. After the results have been stored, the results can be accessed in the memory medium and used by any of the method or system embodiments described herein, formatted for display to a user, used by another software module, method, or system, etc. Furthermore, the results may be stored “permanently,” “semi-permanently,” “temporarily,” or for some period of time. For example, the memory medium may be random access memory (RAM), and the results may not necessarily persist indefinitely in the memory medium.

It is further contemplated that each of the embodiments of the method described above may include any other step(s) of any other method(s) described herein. In addition, each of the embodiments of the method described above may be performed by any of the systems described herein.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable and/or wirelessly interacting components, and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. A transfer head of an electronic component handling system comprising:
a plurality of brackets;
a plurality of front pickup shafts and a plurality of rear pickup shafts slidably coupled to the plurality of brackets along a first axis, wherein at least one of the plurality of front pickup shafts and the plurality of rear pickup shafts are couplable to a pick-up gear;
a first axis pitch-change sub-system comprising:
a set of front anchor blocks and a set of rear anchor blocks slidably coupled along the first axis to a first frame support and a second frame support;
a set of front slide rods coupled to the set of front anchor blocks, wherein the plurality of front pickup shafts is slidably coupled to the set of front slide rods along a second axis; and
a set of rear slide rods coupled to the set of rear anchor blocks, wherein the plurality of rear pickup shafts are slidably coupled to the set of rear slide rods along the second axis, wherein a sliding between the set of front anchor blocks and the set of rear anchor blocks causes a change in pitch between the plurality of front pickup shafts and the plurality of rear pickup shafts along the first axis; and
a second axis pitch-change sub-system comprising:
a cam comprising a plurality of cam slots configured to engage the plurality of brackets, wherein a movement of the cam causes a change in pitch between the plurality of brackets and a corresponding change in pitch between the plurality of front pickup shafts and the plurality of rear pickup shafts along the second axis, wherein one or more brackets of the plurality of brackets further comprises a center shaft coupled to a pick-up gear, wherein a translation of the set of front anchor blocks and the set of rear anchor blocks causes a change in pitch along the first axis between the center shaft and a one or more front pickup shafts of the plurality of front pickup shafts, and between the center shaft and one or more rear pickup shafts of the plurality of rear pickup shafts.

2. The transfer head of claim 1, wherein at least one bracket of the plurality of brackets comprises:
an engagement leg mechanically coupled to a cam slot of the plurality of cam slots at an engagement window.

3. The transfer head of claim 2, wherein pitches between each cam slot changes over a length of the plurality of cam slots, wherein a change in pitch of between one or more cam slots of the plurality of cam slots at the engagement window corresponds to a change in pitch along the second axis of the plurality of brackets.

4. The transfer head of claim 3, wherein the cam comprises a drum cam, wherein a rotation of the drum cam causes the change in pitch of the plurality of cam slots at the engagement window that corresponds to the change in pitch along the second axis of the plurality of brackets.

5. The transfer head of claim 2, wherein one or more of the plurality of front pickup shafts further comprises a latch mechanism configured to lock the one or more of the plurality of front pickup shafts in an inactive configuration.

6. The transfer head of claim 5, wherein the latch mechanism is activated by biasing the one or more of the plurality of front pickup shafts from an active configuration to the inactive configuration.

7. The transfer head of claim 2, wherein one or more of the plurality of front pickup shafts and one or more of the plurality of rear pickup shafts further comprise shaft outlets couplable to vacuum tubing.

8. The transfer head of claim 2, further comprising at least one actuator mechanically coupled to one or more of the plurality of front pickup shafts and configured to raise and lower the pick-up gear of the one or more of the plurality of front pickup shafts.

9. The transfer head of claim 8, wherein the at least one actuator comprises a pneumatic cylinder.

10. The transfer head of claim 1, wherein the pick-up gear comprises, or is couplable to, a nozzle.

11. The transfer head of claim 1, wherein one or more brackets of the plurality of brackets further comprises a center shaft coupled to a pick-up gear, wherein a translation of the set of front anchor blocks and the set of rear anchor blocks causes a change in pitch along the first axis between the center shaft and a one or more front pickup shafts of the plurality of front pickup shafts, and between the center shaft and one or more rear pickup shafts of the plurality of rear pickup shafts.

12. The transfer head of claim 11, wherein the pitch between the center shaft and one or more front pickup shafts of the plurality of front pickup shafts is synchronized with the pitch between the center shaft and the one or more rear pickup shafts of the plurality of rear pickup shafts.

13. The transfer head of claim 1, wherein the first axis pitch-change sub-system further comprises:
a gear system mechanically coupled to at least one set of anchor blocks; and
a motor mechanically coupled to the gear system, wherein an activation of the motor causes the set of front anchor blocks to translate relative to the set of rear anchor blocks.

14. The transfer head of claim 1, wherein the second axis pitch-change sub-system further comprises:
cam gearing mechanically coupled to the cam; and
a cam motor.

15. The transfer head of claim 1, wherein the pick-up gear is couplable to more than one nozzle.

16. The transfer head of claim 1, wherein the cam comprises a wedge cam.

17. The transfer head of claim 1, wherein at least one front pickup shaft of the plurality of front pickup shafts is slidably coupled to one or more brackets of the plurality of brackets via a front pickup shaft slot.

18. An electronic component handling system comprising:
a transfer head comprising:
a plurality of brackets;
a plurality of front pickup shafts and a plurality of rear pickup shafts slidably coupled to the plurality of brackets along a first axis, wherein at least one of the plurality of front pickup shafts and the plurality of rear pickup shafts are couplable to a pick-up gear;
a first axis pitch-change sub-system comprising:
a set of front anchor blocks and a set of rear anchor blocks slidably coupled along the first axis to a first frame support and a second frame support;
a set of front slide rods coupled to the set of front anchor blocks, wherein the plurality of front pickup shafts is slidably coupled to the set of front slide rods along a second axis; and
a set of rear slide rods coupled to the set of rear anchor blocks, wherein the plurality of rear pickup shafts are slidably coupled to the set of rear slide rods along the second axis, wherein a sliding between the set of front anchor blocks and the set of rear anchor blocks causes a change in pitch between the plurality of front pickup shafts and the plurality of rear pickup shafts along the first axis; and
a second axis pitch-change sub-system comprising:
a cam comprising a plurality of cam slots configured to engage the plurality of brackets, wherein a movement of the cam causes a change in pitch between the plurality of brackets and a corresponding change in pitch between the plurality of front pickup shafts and the plurality of rear pickup shafts along the second axis, wherein one or more brackets of the plurality of brackets further comprises a center shaft coupled to a pick-up gear, wherein a translation of the set of front anchor blocks and the set of rear anchor blocks causes a change in pitch along the first axis between the center shaft and a one or more front pickup shafts of the plurality of front pickup shafts, and between the center shaft and one or more rear pickup shafts of the plurality of rear pickup shafts; and
a transfer head parking station.

19. The electronic component handling system of claim 18, wherein at least one bracket of the plurality of brackets comprises:
an engagement leg mechanically coupled to a cam slot of the plurality of cam slots at an engagement window.

20. The electronic component handling system of claim 18, wherein the transfer head parking station comprises:
a pusher assembly comprising:
a base; and
a set of pushers configured to bias a set of nozzles the transfer head from an active position to an inactive position.

21. The electronic component handling system of claim 18, wherein at least one of the transfer head or the transfer head parking station includes one or more sensors configured to detect at least one of an active state, a position, or an orientation, of one or more nozzles.

22. A method for transferring electronic components from a first location to a second location comprising:
acquiring a first plurality of electronic components via a plurality of vacuum nozzles of a transfer head, wherein the plurality of vacuum nozzles are mechanically coupled to a plurality of front pickup shafts and a plurality of rear pickup shafts, wherein the plurality of front pickup shafts and the plurality of rear pickup shafts are slidably coupled to a plurality of brackets;
releasing the first plurality of electronic components at a process site;
adjusting a first axis pitch of the plurality of vacuum nozzles by translating along the plurality of brackets the plurality of front pickup shafts relative to the plurality of rear pickup shafts;
adjusting a second axis pitch via articulating a cam relative to the plurality of brackets, wherein the cam comprises a plurality of cam slots mechanically coupled to the plurality of brackets that guide a translation of the plurality of brackets along a second axis, wherein adjusting the second axis pitch and the first axis pitch of the plurality of vacuum nozzles changes the plurality of vacuum nozzles from a first configuration to a second configuration;
acquiring a second plurality of electronic components via the plurality of vacuum nozzles of the transfer head; and
releasing the second plurality of electronic components at the process site.

23. The method of claim 22, further comprising, after acquiring the second plurality of electronic components and before releasing the second plurality of electronic components, adjusting the first axis pitch and the second axis pitch from the second configuration to a third configuration.

24. A method for transferring electronic components from a first location to a second location comprising:
acquiring a plurality of electronic components via a plurality of vacuum nozzles of a transfer head at the first location, wherein the plurality of vacuum nozzles are mechanically coupled to a plurality of front pickup shafts and a plurality of rear pickup shafts, wherein the plurality of front pickup shafts and a plurality of rear pickup shafts are slidably coupled to a plurality of brackets;
adjusting a first axis pitch of the plurality of vacuum nozzles by translating along the plurality of brackets the plurality of front pickup shafts relative to the plurality of rear pickup shafts;
adjusting a second axis pitch via articulating a cam relative to the plurality of brackets, wherein the cam comprises a plurality of cam slots mechanically coupled to the plurality of brackets that guide a translation of the plurality of brackets along a second axis, wherein adjusting the second axis pitch and the first axis pitch of the plurality of vacuum nozzles changes the plurality of vacuum nozzles from a first configuration to a second configuration; and
moving the transfer head to the second location.

25. The method of claim 24, wherein the first axis pitch and the second axis pitch of the plurality of vacuum nozzles are adjusted simultaneously.

26. The method of claim 25, further comprising adjusting a height of one or more nozzles of the plurality of vacuum nozzles.

27. The method of claim 26, wherein adjusting the height of one or more nozzles of the plurality of vacuum nozzles is performed simultaneously with the adjustment of the first axis pitch and the second axis pitch of the plurality of vacuum nozzles.
